(19) United States
(12) Patent Application Publication
(10) Pub. No.: US 2006/0030057 A1
(43) Pub. Date: Feb. 9, 2006

(54) Insulating film, capacitive element and semiconductor storage device including the insulating film, and fabrication methods thereof

(76) Inventors: Shinichiro Hayashi, Osaka (JP); Toru Nasu, Kyoto (JP)

Correspondence Address: MCDERMOTT WILL & EMERY LLP, 600 13TH STREET, N.W., WASHINGTON, DC, 20005-3096, US

(21) Appl. No.: 11/194,692

(22) Filed: Aug. 2, 2005

(30) Foreign Application Priority Data
Aug. 5, 2004 (JP) 2004-229021

(51) Int. Cl. H01L 21/00; H01L 29/94; H01L 21/8242

(52) U.S. Cl. 438/3; 438/240; 257/295

(57) ABSTRACT

A capacitive element comprises: a lower electrode formed above a semiconductor substrate; a capacitive insulating film formed of a ferroelectric on the lower electrode so as to have a thickness of 100 nm or less; and an upper electrode formed on the capacitive insulating element. In any cross section of the capacitive insulating film which is perpendicular to the semiconductor substrate, a sum of the widths of voids generated in the capacitive insulating film which are measured in a direction perpendicular to the thickness direction of the capacitive insulating film is 20% or less of a unit width.

### CROSS-REFERENCE TO RELATED APPLICATION

This application claims priority under 35 U.S.C. §119(a) on Japanese Patent Application No. 2004-229021 filed on Aug. 5, 2004, the entire contents of which are hereby incorporated by reference.

### BACKGROUND OF THE INVENTION

The present invention relates to a ferroelectric insulating film, a capacitive element and semiconductor device including the insulating film, and fabrication methods thereof.

In recent years, a ferroelectric film having spontaneous polarization characteristics has been studied actively for the purpose of realizing practical use of a nonvolatile memory device capable of lower voltage operation and high-speed writing and reading. Especially for the purpose of realizing a semiconductor storage device on the order of megabits on an LSI formed by a CMOS device based on a design rule of 0.18 μm or smaller, a semiconductor device having a stack structure that achieves a large capacity within a small occupation area has been developed.

To form a capacitive element having this stack structure, a ferroelectric film has to be formed as a capacitive insulating film on a lower electrode which has a shape of a concavity or convexity. In this process, the surface of the ferroelectric film has to be as smooth as possible in order to prevent current leakage through the ferroelectric film.

In an LSI formed by a CMOS device based on a design rule of 0.18 μm or smaller, the supply voltage is 2 V or lower. Therefore, the ferroelectric film has to be thin, for example, 100 nm to 90 nm or less. Thus, to form a highly-reliable ferroelectric film, the influence of a void generated in the ferroelectric film has to be considered.

A known method for forming a ferroelectric film which has a smooth surface and causes no current leakage (see, for example, Japanese Laid-Open Patent Publication No. 2001-237384) is described below.

FIG. 13A to FIG. 13G illustrate a method for forming a capacitive element by showing a cross-sectional structure thereof in the order of production steps. As shown in FIG. 13A, platinum (Pt) is sputtered over a silicon substrate 71 to form a lower electrode 72 having a thickness of 200 nm to 300 nm. Then, precursor solution 73 containing SrBi₂Ta₂O₉ (SBT) dissolved therein, which is a ferroelectric material, is applied and flattened by a spin coater over the lower electrode 72 as shown in FIG. 13B. The resultant structure is dried for 5 minutes using a hot plate maintained at 150° C. to 200° C. such that the solvent is sufficiently volatilized away (FIG. 13C). The resultant structure is subjected to oxygen annealing in a furnace at 800° C. for 30 minutes, whereby the SBT precursor film 73 is crystallized into a crystalline SBT film 74. Since the SBT precursor film 73 is thermally treated at 700° C. or higher, the SBT film 74 has a perovskite structure as a result of dislocation.

The process from the step of FIG. 13B to the step of FIG. 13C is repeated, whereby a SBT film 75 having a thickness of about 150 nm is obtained as shown in FIG. 13D. Then, a flattening film 76 is formed of the SBT precursor material so as to have a thickness of about 30 nm such that irregularities of the SBT film 75 are eliminated as shown in FIG. 13E.

Then, the resultant structure is subjected to oxygen annealing at 600° C. for 30 minutes (FIG. 13F). This annealing is performed under a temperature condition such that the amorphous flattening film 76 is partially transformed into pyrochlore crystal. As a result, the flattening film 76 changes into a SBT film 77 which mixedly contains an amorphous regions and a pyrochlore crystal region which is paraelectric phase.

Thereafter, a platinum (Pt) film having a thickness of 200 nm to 300 nm, which is to be an upper electrode 78, is formed by sputtering. The resultant structure is subjected to oxygen annealing at 800° C. for 30 minutes such that the SBT film 77 is completely crystallized, whereby a perovskite ferroelectric film including a plurality of stacked SBT films is completed.

As described above, application of a material and crystallization of the applied material are repeated such that irregularities generated in the surface during crystallization are eliminated by application of a material for an overlying layer. Further, in the uppermost layer, crystallization of ferroelectric is carried out after the formation of the upper electrode, whereby generation of irregularities is suppressed. Thus, a ferroelectric film having a smooth surface can be obtained.

### SUMMARY OF THE INVENTION

However, in the above-described conventional example, generation of voids in the ferroelectric cannot be prevented although the surface of the ferroelectric film can be smoothed.

In the conventional example, during crystallization of the uppermost ferroelectric film, the crystal structure changes into a more compact structure, and accordingly, the ferroelectric film shrinks. As a result, very small voids are generated in the ferroelectric film. The very small voids are negligible when the ferroelectric film is thick. However, when the thickness of the ferroelectric film is decreased for downsizing the capacitive element, the proportion of the voids to the film thickness increases. This causes a deterioration in the polarization characteristics of the ferroelectric. Especially when the thickness of the ferroelectric film is 100 nm to 90 nm or less so as to comply with the design rule of 0.18 μm, the influence of the voids is large, resulting in a significant deterioration in ferroelectric characteristics.

The present invention overcomes the above-described problems of the conventional technique. An objective of the present invention is to provide an insulating film which is formed of a ferroelectric film with no voids and no deterioration in ferroelectric characteristics. Another objective of the present invention is to provide a capacitive element with small current leakage and high breakdown voltage which is formed using the insulating film.

In order to achieve the above objectives, according to the present invention, the proportion of voids in an insulating film of ferroelectric is smaller than a predetermined value.

Specifically, an insulating film of the present invention comprises a ferroelectric film formed above a substrate, wherein in any cross section of the ferroelectric film which is perpendicular to the substrate, a sum of the widths of voids generated in the ferroelectric film which are measured in a direction perpendicular to the thickness direction of the ferroelectric film is 20% or less of a unit width.

According to the insulating film of the present invention, the substantial area of the insulating film is not decreased by voids, and therefore, deterioration in the characteristics of the insulating film due to voids rarely occurs. As a result, the performance of the insulating film does not deteriorate even when the thickness of the insulating film is decreased and miniaturization is advanced. The “unit width” of the insulating film means the width of a portion of the insulating film which is shown on a cross section and discharges the functions of the insulating film.

In the insulating film of the present invention, the ferroelectric film preferably has a thickness of 100 nm or less. Even under such a condition, the performance of the insulating film can be maintained.

In the insulating film of the present invention, the ferroelectric film is preferably formed of any one of (Sr_{w}CaₓBa_{1-w-x})Bi₂(Ta_{y}Nb_{z}V _{1-y-z})₂O₉ (w, x, y, and z are in the range of 0 to 1, w+x and y+z are 1 or less), Pb(HfₓZr_{y}Ti_{1-x-y})O₃ (x and y are in the range of 0 to 1, x+y is 1 or less), and (Bi_{w}NdₓLa_{1-w-x})₄(Hf_{y}Zr_{z}Ti_{3-y-z})O₁₂ (w, x, y, and z are in the range of 0 to 1, w+x and y+z are 1 or less). With this structure, an insulating film of a ferroelectric is surely realized.

In the insulating film of the present invention, the ferroelectric film is preferably a capacitive insulating film of a capacitive element of a semiconductor storage device. The ferroelectric film may be a gate insulating film of a ferroelectric field effect transistor. With this structure, the functions of the insulating film can be surely discharged.

A capacitive element of the present invention comprises: a lower electrode formed above a semiconductor substrate; a capacitive insulating film formed of a ferroelectric on the lower electrode so as to have a thickness of 100 nm or less, wherein in any cross section of the capacitive insulating film which is perpendicular to the semiconductor substrate, a sum of the widths of first voids generated in the capacitive insulating film which are measured in a direction perpendicular to the thickness direction of the capacitive insulating film is 20% or less of a unit width; and an upper electrode formed on the capacitive insulating element.

According to the present invention, the substantial area of the insulating film is not decreased by voids, and therefore, deterioration in the characteristics of the insulating film due to voids rarely occurs. As a result, a capacitive element with small current leakage and high breakdown voltage can be realized.

In the capacitive element of the present invention, in any of the upper electrode and the lower electrode, a sum of the widths of second voids generated in the electrode which are measured in a direction perpendicular to the thickness direction of the electrode is preferably 20% or less of a unit width. With this structure, a capacitive element is realized wherein the electrodes contain no voids and the voltage applied to the capacitive insulating film does not decrease.

In the capacitive element of the present invention, the thickness of the capacitive insulating film is preferably in the range of 12.5 nm to 90 nm. With this structure, a high-performance capacitive element is surely realized without causing voids by a grain size difference during crystallization.

In the capacitive element of the present invention, at least one of the lower electrode and the upper electrode is preferably a multilayered film. With this structure, it is possible to add an oxygen barrier property to the electrode and to decrease the contact resistance with a wire.

In the capacitive element of the present invention, preferably, at least one of the lower electrode and the upper electrode contains a conductive metal oxide; and the conductive metal oxide is in contact with the capacitive insulating film. With this structure, a capacitive element with no voids in the electrodes can be surely realized.

In the capacitive element of the present invention, at least one of the lower electrode and the upper electrode is preferably a multilayered film. With this structure, the stress which is applied to the lower electrode, the capacitive insulating film and the upper electrode is dispersed. Therefore, generation of voids in the lower electrode, the capacitive insulating film and the upper electrode is suppressed.

In the capacitive element of the present invention, preferably, each of the lower electrode and the upper electrode is a single-layer film or a multilayered film; and each of a film included in the lower electrode which is in contact with the capacitive insulating film and a film included in the upper electrode which is in contact with the capacitive insulating film has a thickness in the range of 10 nm to 200 nm. With this structure, deterioration in the characteristics of the capacitive element which would be caused by the electrodes can surely be prevented.

In the capacitive element of the present invention, the voltage applied to the capacitive insulating film is preferably in the range of 0.3 V to 1.8 V. The strength of an electric field applied to the capacitive insulating film is preferably 200 kV/cm or greater. With this structure, the ratio of the electric charge amount for determining data “0” and data “1” stored in the capacitive element has a sufficiently large value, and therefore, desirable data storage characteristics can be realized.

In the capacitive element of the present invention, preferably, the capacitive insulating film is in contact with the upper or lower surface of the lower electrode; and the ratio of height to width of the lower electrode is 1 or greater. Preferably, the capacitive element is formed in an opening provided in an interlayer insulating film formed on the semiconductor substrate; and the ratio of depth to diameter of the opening is 1 or greater. With this structure, the surface area of the capacitive insulating film is increased so that the electric charges for data storage are sufficiently accumulated, and desirable polarization characteristics can be realized.

In the capacitive element of the present invention, the ferroelectric is preferably any one of (Sr_{w}CaₓBa_{1-w-x})Bi₂(Ta_{y}Nb_{z}V_{1-y-z})₂O₉ (w, x, y, and z are in the range of 0 to 1, w+x and y+z are 1 or less), Pb(HfₓZr_{y}Ti_{1-x-y})O₃ (x and y are in the range of 0 to 1, x+y is 1 or less), and (Bi_{w}NdₓLa_{1-w-x})₄(Hf_{y}Zr_{z}Ti_{3-y-z})O₁₂ (w, x, y, and z are in the range of 0 to 1, w+x and y+z are 1 or less). With this structure, a capacitive insulating film of a ferroelectric can surely be realized.

A semiconductor storage device of the present invention comprises: a capacitive element of the present invention; a transistor formed on the semiconductor substrate, the transistor including a source region and a drain region; an interlayer insulating film which covers the transistor; and a plug electrode formed in the interlayer insulating film, one end of the plug electrode being electrically connected to the source region or the drain region, the other end of the plug electrode being electrically connected to the lower electrode of the capacitive element.

According to the semiconductor storage device of the present invention, miniaturization of a capacitive element can be achieved without deteriorating the reliability of the capacitive element. Thus, a highly-reliable, densely-integrated semiconductor storage device can be realized.

A capacitive element fabrication method of the present invention comprises the steps of: (a) forming a lower electrode above a semiconductor substrate; (b) forming a precursor film of a capacitive insulating film of a ferroelectric on the lower electrode by a metal organic chemical vapor deposition method; (c) forming an upper electrode on the precursor film; and (d) crystallizing the precursor film by a thermal treatment to form a capacitive insulating film.

In the capacitive element fabrication method of the present invention, voids are rarely generated by shrinkage, and in addition, a capacitive insulating film having a smooth surface can be formed. Thus, a capacitive element with small current leakage and high breakdown voltage can readily be obtained.

In the capacitive element fabrication method of the present invention, step (d) is preferably performed after step (c). With this structure, volatilization of constituent elements from the precursor film during a thermal treatment can be prevented.

In the capacitive element fabrication method of the present invention, the ferroelectric is preferably any one of (Sr_{w}CaₓBa_{1-w-x})Bi₂(Ta_{y}Nb_{z}V_{1-y-z})₂O₉ (w, x, y, and z are in the range of 0 to 1, w+x and y+z are 1 or less), Pb(HfₓZr_{y}T_{1-x-y})O₃ (x and y are in the range of 0 to 1, x+y is 1 or less), and (Bi_{w}NdₓLa_{1-w-x})₄(Hf_{y}Zr_{z}Ti_{3-y-z})O₁₂ (w, x, y, and z are in the range of 0 to 1, w+x and y+z are 1 or less). With this structure, a capacitive insulating film of a ferroelectric can surely be formed.

In the capacitive element fabrication method of the present invention, preferably, step (d) includes a first thermal treatment through which the nuclei density is determined and a second thermal treatment for crystal growth; and the grain size of the capacitive insulating film is in the range of 0 nm to 200 nm. With this structure, generation of voids which would be caused by a grain size difference of the capacitive insulating film can be prevented.

In the capacitive element fabrication method of the present invention, the thickness of the capacitive insulating film is preferably in the range of 12.5 nm to 90 nm. With this structure, the polarization characteristics of the capacitive element are surely improved.

In the capacitive element fabrication method of the present invention, preferably, at least one of the lower electrode and the upper electrode contains a conductive metal oxide; and the conductive metal oxide is in contact with the capacitive insulating film. With this structure, shrinkage of the electrodes can be suppressed, and therefore, generation of voids in the electrodes can be prevented.

In the capacitive element fabrication method of the present invention, at least one of the lower electrode and the upper electrode is preferably a multilayered film. With this structure, the stress which is applied to the lower electrode, the capacitive insulating film and the upper electrode, is dispersed. Therefore, generation of voids in the lower electrode, the capacitive insulating film and the upper electrode is suppressed.

In the capacitive element fabrication method of the present invention, preferably, each of the lower electrode and the upper electrode is a single-layer film or a multilayered film; and each of a film included in the lower electrode which is in contact with the capacitive insulating film and a film included in the upper electrode which is in contact with the capacitive insulating film has a thickness in the range of 10 nm to 200 nm. With this structure, the strength of the electric field applied to the capacitive insulating film can surely be secured without an adverse effect of the electrodes on the capacitive insulating film during crystallization of the capacitive insulating film.

In the capacitive element fabrication method of the present invention, the capacitive element preferably has a three-dimensional geometry such that the capacitive insulating film covers not only an upper surface but also a side surface of the lower electrode. The ratio of height to width of the lower electrode is preferably 1 or greater. The fabrication method further comprises, prior to the step of forming the lower electrode: forming an insulating film on the semiconductor substrate; and etching the insulating film to form an opening. The step of forming the lower electrode includes forming the lower electrode on a bottom and side wall of the opening. The ratio of depth to diameter of the opening may be 1 or greater. With this structure, a sufficient surface area of the capacitive insulating film is secured.

In the capacitive element fabrication method of the present invention, the upper electrode is preferably formed by a metal organic chemical vapor deposition method.

In the capacitive element fabrication method of the present invention, at step (d), shrinkage of the precursor film is preferably 15% or less. Further, at step (d), shrinkage of the upper electrode and the lower electrode is preferably 10% or less. With this structure, generation of voids is prevented, and a high-performance capacitive element is surely obtained.

A semiconductor storage device production method of the present invention comprises the steps of: forming a transistor on a semiconductor substrate, the transistor including a source region and a drain region; forming an interlayer insulating film so as to cover the transistor; forming a plug contact so as to penetrate through the interlayer insulating film, the plug contact being electrically connected to the source region or the drain region; forming a lower electrode on the interlayer insulating film so as to be electrically connected to the plug contact; forming a precursor film of a capacitive insulating film of a ferroelectric on the lower electrode by a metal organic chemical vapor deposition method; forming an upper electrode on the precursor film; and crystallizing the precursor film by a thermal treatment to form a capacitive insulating film.

According to the semiconductor storage device production method of the present invention, the capacitive element is formed using a capacitive element fabrication method of the present invention, and therefore, a semiconductor storage device including a capacitive element with small current leakage and high breakdown voltage can be produced. Thus, miniaturization of the capacitive element can be realized without deteriorating the reliability. As a result, a highly-reliable, densely-integrated semiconductor storage device can readily be realized.

An insulating film fabrication method of the present invention comprises the steps of: forming a precursor film of a ferroelectric film above a semiconductor substrate by a metal organic chemical vapor deposition method; and crystallizing the precursor film by a thermal treatment to form a ferroelectric film, wherein in the thermal treatment, shrinkage of the precursor film is 15% or less.

According to the insulating film fabrication method of the present invention, the precursor film does not shrink in the thermal treatment. Therefore, voids are rarely generated, and a high performance insulating film can be obtained.

In the insulating film fabrication method of the present invention, the ferroelectric film preferably has a thickness of 100 nm or less. The ferroelectric is preferably any one of (Sr_{w}CaₓBa_{1-w-x})Bi₂(Ta_{y}Nb_{z}V_{1-y-z})₂O₉ (w, x, y, and z are in the range of 0 to 1, w+x and y+z are 1 or less), Pb(HfₓZr_{y}Ti_{1-x-y})O₃ (x and y are in the range of 0 to 1, x+y is 1 or less), and (Bi_{w}NdₓLa_{1-w-x})₄(Hf_{y}Zr_{z}Ti_{3-y-z})O₁₂ (w, x, y, and z are in the range of 0 to 1, w+x and y+z are 1 or less). With this structure, an insulating film of a ferroelectric can surely be realized.

### BRIEF DESCRIPTION OF THE DRAWINGS

FIG. 1A and FIG. 1B are cross-sectional views showing principal part of a semiconductor storage device according to embodiment 1. FIG. 1A shows a cross section taken along a word line. FIG. 1B shows a cross section taken along line Ib-Ib of FIG. 1A.

FIG. 2A, FIG. 2B, FIG. 2C and FIG. 2D are cross-sectional views illustrating a method for producing a semiconductor storage device according to embodiment 1 in the order of production steps.

FIG. 3A, FIG. 3B and FIG. 3C are cross-sectional views illustrating a method for producing a semiconductor storage device according to embodiment 1 in the order of production steps.

FIG. 4 is an electron microscope image showing the state of a cross section of the semiconductor storage device according to embodiment 1.

FIG. 5 is a cross-sectional view showing the state of voids in the semiconductor storage device according to embodiment 1.

FIG. 6 is a graph comparatively showing the void occupancy rate in a capacitive insulating film according to embodiment 1 and a conventional capacitive insulating film.

FIG. 7 is a cross-sectional view showing a principal part of a semiconductor storage device according to embodiment 2.

FIG. 8A, FIG. 8B and FIG. 8C are cross-sectional views illustrating a method for producing a semiconductor storage device according to embodiment 2 in the order of production steps.

FIG. 9A, FIG. 9B and FIG. 9C are cross-sectional views illustrating a method for producing a semiconductor storage device according to embodiment 2 in the order of production steps.

FIG. 10 is a cross-sectional view showing a principal part of a semiconductor storage device according to embodiment 3.

FIG. 11 is a graph illustrating the correlation between the thickness of a capacitive insulating film and the residual polarization in a semiconductor device according to embodiment 4.

FIG. 12 is a graph illustrating the correlation between the thickness of an upper electrode and the residual polarization in the semiconductor device according to embodiment 4.

FIG. 13A to FIG. 13G are cross-sectional views illustrating a method for fabricating a conventional capacitive element in the order of production steps.

FIG. 14 is an electron microscope image showing the state of a cross section of a conventional semiconductor storage device.

### DESCRIPTION OF THE PREFERRED EMBODIMENTS

### EMBODIMENT 1

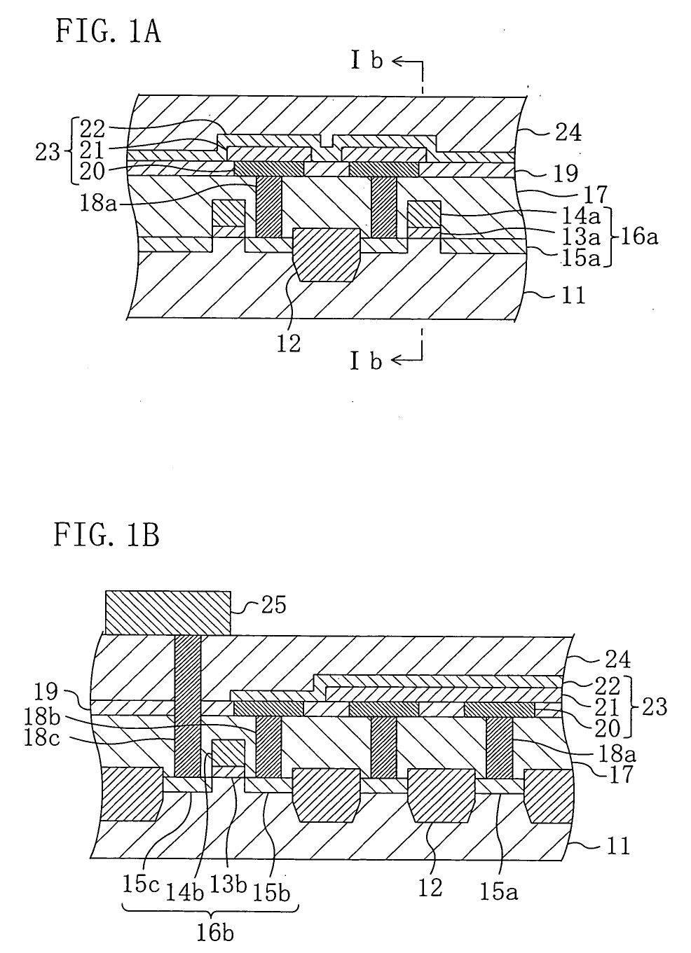

FIG. 1A and FIG. 1B show principal part of a cross-sectional structure of a semiconductor storage device including a capacitive insulating film according to embodiment 1. FIG. 1A shows a cross section taken along a word line. FIG. 1B shows a cross section taken along line Ib-Ib of FIG. 1A, i.e., taken along a bit line.

Referring to FIG. 1A and FIG. 1B, memory cell transistors 16a, a memory cell plate driver transistor 16b, and a capacitive element 23 are provided on a semiconductor substrate 11 of silicon.

Each of the memory cell transistors 16a includes a gate insulating film 13a, a gate electrode 14a and an impurity-diffused region 15a. The semiconductor storage device includes a plurality of memory cell transistors 16a which are arranged in a matrix along the word and bit lines. The memory cell plate driver transistor 16b includes a gate insulating film 13b, a gate electrode 14b and an impurity-diffused region 15b. The memory cell plate driver transistor 16b is provided at an end of each line of memory cell transistors 16a arranged along a bit line. Device isolation regions 12 are provided between the memory cell transistors 16a, between the memory cell plate driver transistors 16b, and between the memory cell transistor 16a and the memory cell plate driver transistor 16b for isolating the transistors.

The memory cell transistors 16a and the memory cell plate driver transistors 16b are covered with a first interlayer insulating film 17 which has a thickness of 500 nm. The first interlayer insulating film 17 is a silicon oxide film to which phosphorus and boron are added (BPSG film). A plurality of capacitive elements 23 are provided over the first interlayer insulating film 17. The capacitive elements 23 correspond to the memory cell transistors 16a.

Each of the capacitive elements 23 includes a lower electrode 20, a capacitive insulating film 21, and an upper electrode 22, which are sequentially formed on the first interlayer insulating film 17. The capacitive elements 23 correspond to the memory cell transistors 16a on a one-to-one basis. The lower electrode 20 is a layered film sequentially including titan aluminum nitride (TiAlN), iridium (Ir) and iridium oxide (IrO₂) from the bottom. The thicknesses of these layers are 100 nm, 50 nm, and 50 to 100 nm, respectively. It should be noted that a platinum (Pt) film of about 100 nm thick may be provided over the iridium oxide (IrO₂) layer. The lower electrode 20 also functions as an oxygen barrier.

The lower electrode 20 is electrically connected to the impurity-diffused region 15a of the memory cell transistors 16a through a first contact plug 18a formed of tungsten in the first interlayer insulating film 17.

The lower electrode 20 is independently provided for each capacitive element 23. Between the lower electrodes 20 is a buried insulating film 19 which is formed of silicon oxide so as to have a thickness of 300 nm, such that the lower electrodes 20 are mutually insulated.

The capacitive insulating film 21 is a ferroelectric film formed of SrBi₂Ta₂O₉ (SBT) so as to have a thickness of 90 nm. The upper electrode 22 is an iridium oxide (IrO₂) or platinum (Pt) film having a thickness of 50 nm. The capacitive insulating film 21 and the upper electrode 22 are common among capacitive elements 23 which are aligned along a bit line. In a region where the capacitive insulating film 21 is not formed, the upper electrode 22 is electrically connected to the impurity-diffused region 15b of the memory cell plate driver transistor 16b through the lower electrode 20 and a second contact plug 18b formed in the first interlayer insulating film 17.

The capacitive elements 23 are covered with a second interlayer insulating film 24 which has a thickness of 300 nm. The second interlayer insulating film 24 is a silicon oxide film formed of O₃ and TEOS (O₃-TEOS film). A wire layer 25, which contains aluminum (Al), is provided on the second interlayer insulating film 24. The wire layer 25 is electrically connected to an impurity-diffused region 15c of the memory cell plate driver transistor 16b through a third contact plug 18c made of tungsten which penetrates through the first interlayer insulating film 17, the second interlayer insulating film 24 and the buried insulating film 19.

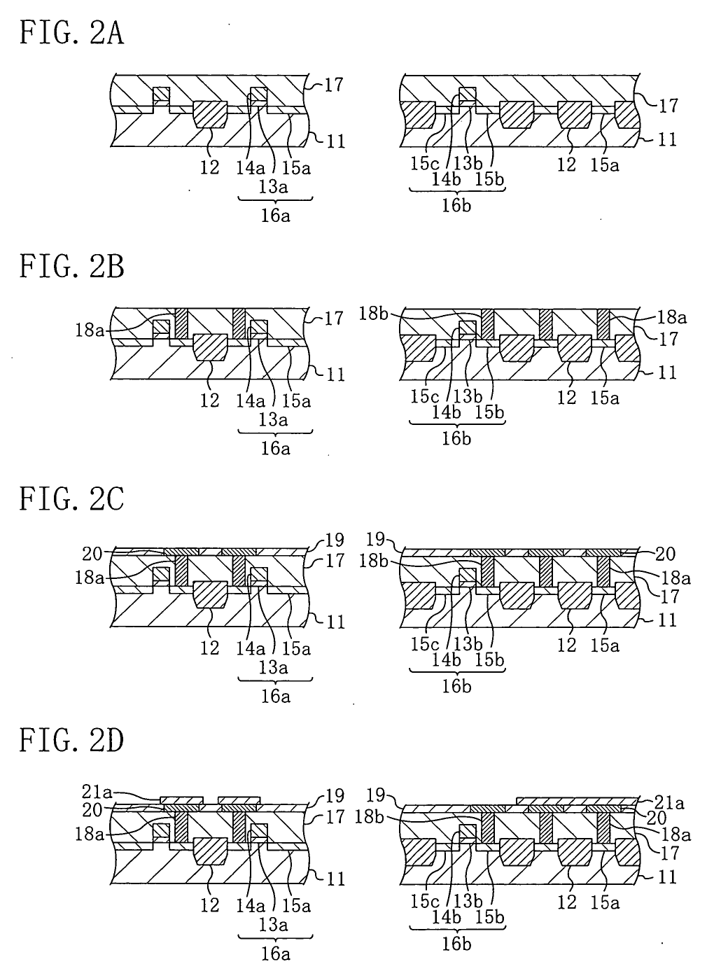

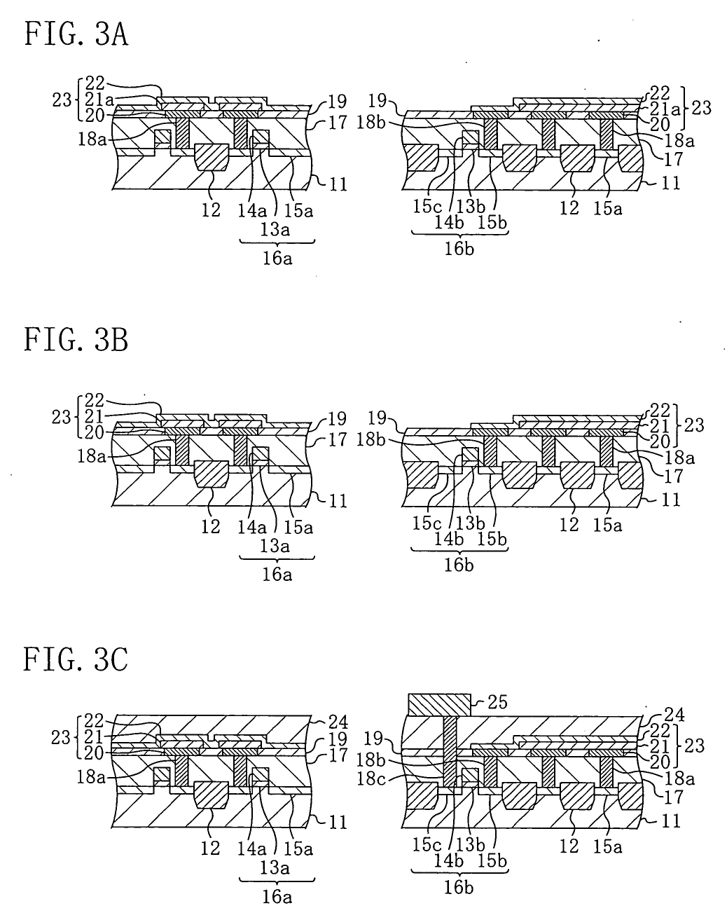

FIG. 2A to FIG. 2D and FIG. 3A to FIG. 3C are cross-sectional views illustrating a method for forming a capacitive insulating film of embodiment 1, a capacitive element and semiconductor storage device including the capacitive insulating film in the order of production steps. Shown on the left side is a cross section taken along a word line. Shown on the right side is a cross section taken along a bit line.

At the first step, device isolation regions 12 are formed of silicon oxide on a silicon substrate 11. Then, a predetermined number of memory cell transistors 16a, which include a gate insulating film 13a, a gate electrode 14a and an impurity-diffused region 15a, and a predetermined number of memory cell plate driver transistors 16b, which include a gate insulating film 13b, a gate electrode 14b, an impurity-diffused region 15b and an impurity-diffused region 15c, are formed along bit lines and word lines. A first interlayer insulating film 17 is formed of BPSG so as to cover the memory cell transistors 16a and the memory cell plate driver transistors 16b as shown in FIG. 2A.

Then, etching is carried out on the first interlayer insulating film 17 to form first contact holes, through which the impurity-diffused region 15a is exposed, and second contact holes, through which the impurity-diffused region 15b is exposed. Tungsten is deposited in the first and second contact holes and on the first interlayer insulating film 17, and the deposited tungsten is polished by a CMP method such that a plurality of first contact plugs 18a and second contact plugs 18b are formed as shown in FIG. 2B.

Then, TiAlN of 100 nm thick, Ir of 50 nm thick, and IrO₂ of 50 to 100 nm thick are sequentially formed on the first interlayer insulating film 17 so as to cover the upper surface of the first contact plugs 18a and second contact plugs 18b and patterned to form lower electrodes 20. Herein, IrO₂ is deposited by MOCVD (metal organic chemical vapor deposition). It should be noted that a Pt film of about 100 nm thick may be further provided on the IrO₂ layer. Then, a buried insulating film 19 is formed of silicon oxide in regions between the lower electrodes 20, resulting in the structure shown in FIG. 2C.

Then, a precursor film 21a is formed of SBT, which is a ferroelectric, by MOCVD on the buried insulating film 19 and the lower electrodes 20. The precursor film 21a is then patterned such that the lower electrodes 20 formed on the second contact plugs 18b are exposed, resulting in the structure shown in FIG. 2D.

Then, IrO₂ or Pt is deposited on the buried insulating film 19, the precursor film 21a and the lower electrodes 20 and patterned into a predetermined shape, whereby an upper electrode 22 is formed as shown in FIG. 3A. Herein, IrO₂ is deposited by MOCVD.

The resultant structure is subjected to a thermal treatment at 500° C. to 700° C., through which the nuclei density of the ferroelectric film is determined. Thereafter, the precursor film 21a is crystallized at 800° C. to form a capacitive insulating film 21. Thus, the lower electrodes 20, the capacitive insulating film 21 and the upper electrode 22 constitute a capacitive element 23.

Then, a second interlayer insulating film 24, which is a O₃-TEOS film, is formed on the upper electrode 22 and the buried insulating film 19. Then, etching is carried out on the second interlayer insulating film 24, the buried insulating film 19 and the first interlayer insulating film 17 to form a third contact hole which reaches the impurity- diffused region 15c of the memory cell plate driver transistors 16b. The third contact hole is filled with tungsten to form a third contact plug 18c. Then, a wire layer 25, which contains aluminum, is formed on the second interlayer insulating film 24 so as to be in contact with the third contact plug 18c, resulting in the structure shown in FIG. 3C.

Although in embodiment 1 the upper electrode 22 is connected to the second contact plug 18b through the lower electrode 20, the upper electrode 22 may be directly connected to the second contact plug 18b without the intervention of the lower electrode 20. It should be noted however that, since the precursor film 21a is sintered in an oxygen atmosphere, the lower electrode 20 is preferably provided between the upper electrode 22 and the second contact plug 18b as an oxygen barrier to prevent oxidation of the second contact plug 18b. With this structure, as a result, production of the storage device is more readily achieved.

In the above example, the memory cell plate driver transistors 16b is provided for establishing an electrical connection between the upper electrode 22 and the wire layer 25. However, alternatively, the second contact plugs 18b and the third contact plug 18c may be connected to the same impurity-diffused region without providing the memory cell plate driver transistors 16b. That is, the impurity-diffused region 15b and the impurity-diffused region 15c may be formed as a single impurity-diffused region.

The ferroelectric film which constitutes the capacitive insulating film 21 may contain Ca or Ba instead of Sr or may contain Sr, Ca and Ba at a certain ratio. Alternatively, the ferroelectric film may contain Nb or V instead of Ta or may contain Ta, Nb and V at a certain ratio.

In the above-described method, the second contact plugs 18b can be formed simultaneously with the first contact plugs 18a. Thus, the plugging step of directly connecting the capacitive insulating film 21 and the wire layer 25, which would be a cause of deterioration in ferroelectric characteristics due to hydrogen, is avoided.

Hereinafter, a method for suppressing generation of voids in the capacitive insulating film 21 is described.

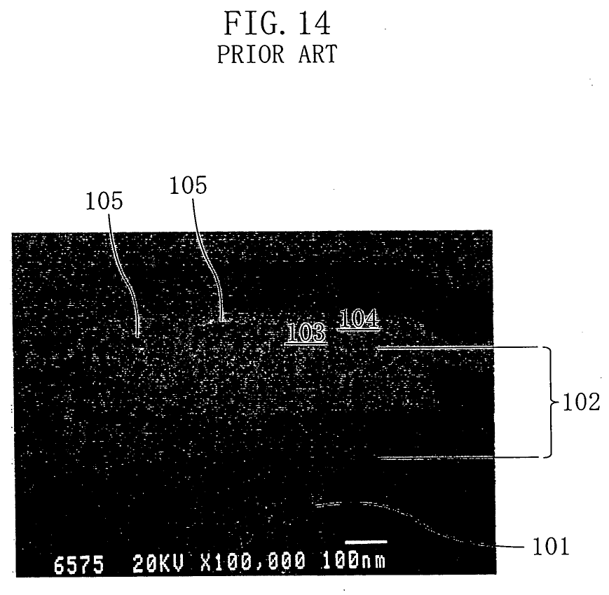

FIG. 14 shows a cross section of a conventional capacitive element formed by repeating application of a ferroelectric solution and crystallization, which was taken through an observation with an electron microscope (SEM). As shown in FIG. 14, a lower electrode 102 sequentially includes, from the bottom, a TiAlN layer of 100 nm thick, an IrO₂ layer of 50 nm thick, an Ir layer of 50 nm thick, and a Pt layer of 100 nm thick. On the lower electrode 102 is a capacitive insulating film 103 of SBT having a thickness of 70 nm. On the capacitive insulating film 103 is an upper electrode 104 of Pt having a thickness of 50 nm. The capacitive insulating film 103 includes large voids 105 which are greater than 50% of the thickness of the capacitive insulating film 103. At the positions where the voids 105 exist, the substantial thickness of the capacitive insulating film 103 is very thin.

These voids are generated through the mechanism described below. In the conventional method where a precursor film of a capacitive insulating film is formed, by applying a solution containing a ferroelectric dissolved therein, an organic component volatilizes away from the precursor film during crystallization of the precursor film, so that the precursor film shrinks 20% or more. As a result, voids are generated in the ferroelectric. Alternatively, when the upper electrode and the lower electrode are formed of a conductive oxide which rarely shrinks during a thermal treatment, the precursor film cannot freely change its shape at a portion where the precursor film is in contact with the upper or lower electrode. Thus, the precursor film largely shrinks in some parts, and accordingly, voids are further generated in the ferroelectric.

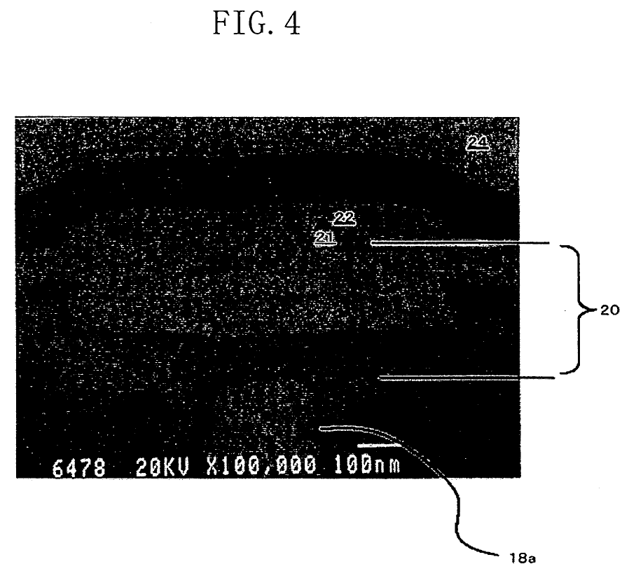

FIG. 4 shows an SEM image of a cross section of a capacitive element formed using the method of embodiment 1. Herein, the upper electrode is IrO₂, and the uppermost layer of the lower electrode 20 is also IrO₂. In FIG. 4, voids are hardly observed in the capacitive insulating film 21 of the capacitive element formed using the method of embodiment 1 even though the upper electrode and the lower electrode are formed of a conductive oxide which scarcely shrinks.

This is because, in embodiment 1, the precursor film 21a of the capacitive insulating film 21 is formed by MOCVD, and accordingly, the shrinkage ratio of this film is small. In crystallization of the precursor film 21a, local shrinkage hardly occurs even in a portion where the precursor film 21a is in contact with the upper electrode 22 or the lower electrode 20. To achieve this effect, shrinkage of the precursor film 21a during crystallization is 15% or less and is preferably 10% or less.

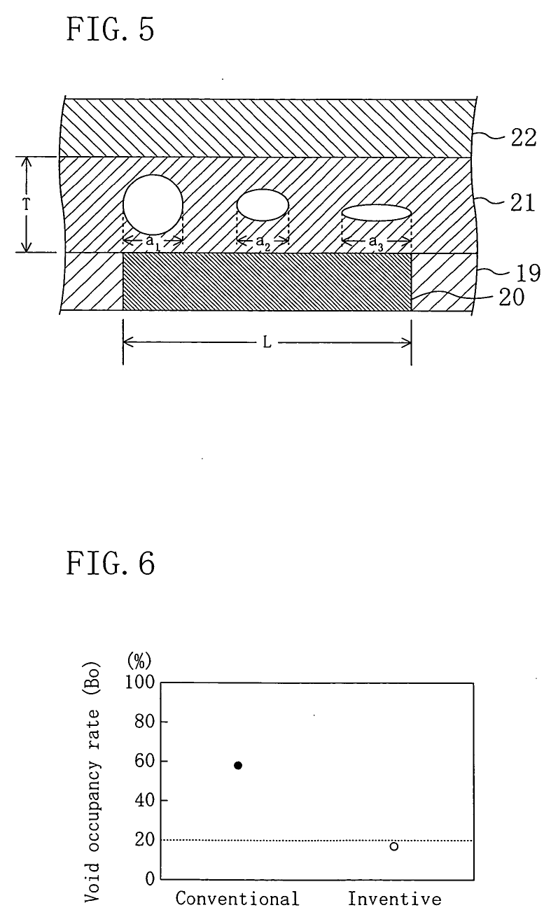

FIG. 5 schematically shows the shapes of voids generated in the capacitive element. FIG. 5 shows a cross section of the capacitive element which is perpendicular to the semiconductor substrate on which the capacitive element is formed. As shown in FIG. 5, the capacitive insulating film 21, which has thickness T and unit width L, is interposed between the upper electrode 22 and the lower electrode 20. Unit width L is. the width of a part of the capacitive insulating film 21 seen on the cross section of FIG. 5 which functions as a capacitive element. The part which functions as a capacitive element is a place where the capacitive insulating film 21, the upper electrode 22 and the lower electrode 20 are stacked. In embodiment 1, this part is defined by the lower electrode 20. Thus, in this case, the length of a portion where the capacitive insulating film 21 is in contact with the lower electrode 20 represents unit width L of the capacitive insulating film 21.

However, voids are generated in the capacitive insulating film 21. As the proportion of the voids in the capacitive insulating film 21 increases, the substantial thickness and area of the capacitive insulating film 21 decrease, and the characteristics of the capacitive element deteriorate. The influence of such voids on the capacitive element can be assessed using the proportion of void portions to the thickness of the capacitive insulating film 21 and the proportion of void portions to the unit width of the capacitive insulating film 21 as indices.

For example, the total width of the void portions in the cross section of FIG. 5 is the sum of the widths of cross sections of the void portions taken along a direction perpendicular to the thickness direction of the capacitive insulating film 21, i.e., the sum of a1, a2 and a3. The unit width of the capacitive insulating film 21 in the cross sections of FIG. 5 is width L of a portion where the lower electrode 20 and the capacitive insulating film 21 are in contact with each other. Thus, the occupancy of the void portions, Bo, can be obtained by dividing width a of the cross section of the void portions by unit width L of the capacitive insulating film 21. In the example of FIG. 5, the occupancy of the voids, Bo, is Bo=(a1+a2+a3)/L. It should be noted that when a void overlaps another one, the overlapping portion is ignored. In the case of a structure wherein the capacity of the capacitive element is determined by the area of the upper electrode, the length of the boundary between the upper electrode and the capacitive insulating film may be considered as unit width L.

As value Bo decreases, the size of a void generated in the capacitive insulating film decreases, and the proportion of the void in the capacitive insulating film also decreases. Therefore, a capacitive element with small current leakage and high breakdown voltage can be realized.

FIG. 6 shows a comparison of typical values of Bo between a capacitive insulating film formed using the method of embodiment 1 and a capacitive insulating film formed using a conventional method. We prepared samples of the capacitive insulating films formed using the method of embodiment 1 and a conventional method which were cleaved at a certain position using a focused ion beam (FIB). Then, we obtained SEM images from the cross sections of the cleaved samples. We measured the width of voids that appeared on the SEM image using a scale shown on the SEM image to calculate value Bo.

As seen from FIG. 6, a capacitive insulating film which has value Bo of 20% or smaller can be surely formed using the method of embodiment 1, whereas value Bo is not 20% or smaller in the capacitive insulating film formed using the conventional method.

Especially when the lower electrode 20 and the upper electrode 22, which are in contact with the capacitive insulating film, are formed of IrO₂, value Bo is 10% or smaller. This is because IrO₂ shrinks only about 10% in crystallization of the precursor film 21a, whereas Pt shrinks about 20% in the crystallization. As a result, in the capacitive element wherein the lower electrode 20 and the upper electrode 22 are formed of IrO₂, generation of voids is small, and value Bo is further decreased, as compared with a structure wherein the electrodes 20 and 22 are formed of Pt.

Since the variation in grain size is bigger in IrO₂ than in Pt, generation of voids in the lower electrode 20 and the upper electrode 22 can also be suppressed. In the case where voids are generated in the upper and lower electrodes, the substantial thickness and area of the electrodes decrease. As a result, there is a possibility that the voltage applied to the capacitive insulating film decreases or that the capacity of the capacitive insulating film decreases. Thus, the characteristics of the capacitive element can be improved by decreasing value Bo, as described above, also in the upper and lower electrodes. It should be noted that the same effects can be achieved even when a conductive metal oxide, such as RuO₂, SrRuO₃, or the like, is used in place of IrO₂.

As described above, a capacitive insulating film of embodiment 1 used in a capacitive element can prevent the increase in current leakage and the decrease in voltage resistance. Furthermore, the capacitive insulating film of embodiment 1 is resistant to stress migration and is highly reliable. Thus, a highly-reliable, densely-integrated semiconductor storage device can be realized using the capacitive insulating film of embodiment 1.

### EMBODIMENT 2

Hereinafter, embodiment 2 of the present invention is described with reference to the drawings.

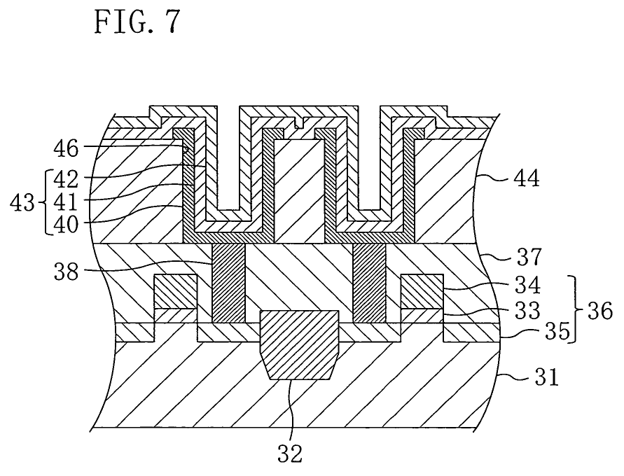

FIG. 7 shows principal part of a capacitive insulating film of embodiment 2 and a capacitive element and semiconductor storage device including the capacitive insulating film in a cross section taken along a word line. The capacitive element of embodiment 2 has a three-dimensional geometry such that the capacitive insulating film covers not only the upper surface but also the side surface of the lower electrode. More specifically, the capacitive element of embodiment 2 has a so-called “concave” electrode as shown in FIG. 7.

As shown in FIG. 7, a pair of memory cell transistors 36 and a capacitive element 43 are provided on a semiconductor substrate 32 made of silicon.

The memory cell transistor 36 includes a gate insulating film 33, a gate insulating film 34 and an impurity-diffused region 35. A device isolation region 32 is provided between the memory cell transistors 36 for isolating the transistors.

The memory cell transistors 36 are covered with a first interlayer insulating film 37 which has a thickness of 500 nm. The first interlayer insulating film 37 is made of silicon oxide (SiO₂) or silicon nitride (SiN). Provided over the first interlayer insulating film 37 is a second interlayer insulating film 44 which has a thickness of 300 nm. The second interlayer insulating film 44 is made of silicon oxide (SiO₂) or silicon nitride (SiN).

The second interlayer insulating film 44 has an opening 46 through which the first interlayer insulating film 37 is exposed. The bottom and side wall of the opening 46 are covered with a lower electrode 40. The lower electrode 40 is a single-layer film or a multilayered film, which includes at least one of Ir, IrO₂, Ru, RuO₂, TiAlN, TaAlN, TiSiN and TaAlN. In the case where the lower electrode 40 is a multilayered film, the lower electrode 40 includes a lower layer which functions as an oxygen barrier and an upper layer formed of a conductive metal oxide, such as IrO₂, RuO₂, or SrRuO₃, which is in contact with the capacitive insulating film. The thickness of the upper layer which is in contact with the capacitive insulating film is preferably 10 nm to 200 nm.

A capacitive insulating film 41 having a thickness of 12.5 nm to 90 nm is provided on the second interlayer insulating film 44 so as to cover the lower electrode 40 formed in the opening 46. The capacitive insulating film 41 is made of SrBi₂(TaₓNb₁₋ₓ)₂O₉(SBTN: 0≦x≦1), which is a ferroelectric.

Provided on the capacitive insulating film 41 is an upper electrode 42 having a thickness of 10 nm to 200 nm. The upper electrode 42 is made of a conductive oxide, such as IrO₂, RuO₂, SrRuO₃, or the like.

The lower electrode 40 is connected to the impurity-diffused region 35 of the memory cell transistor 36 through a contact plug 38 provided in the first interlayer insulating film 37.

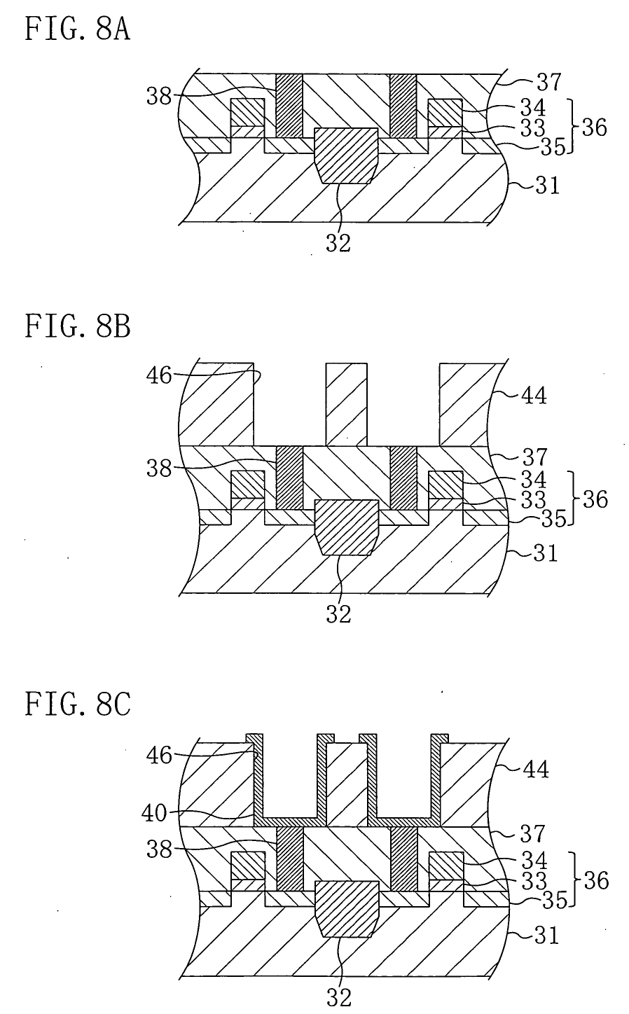

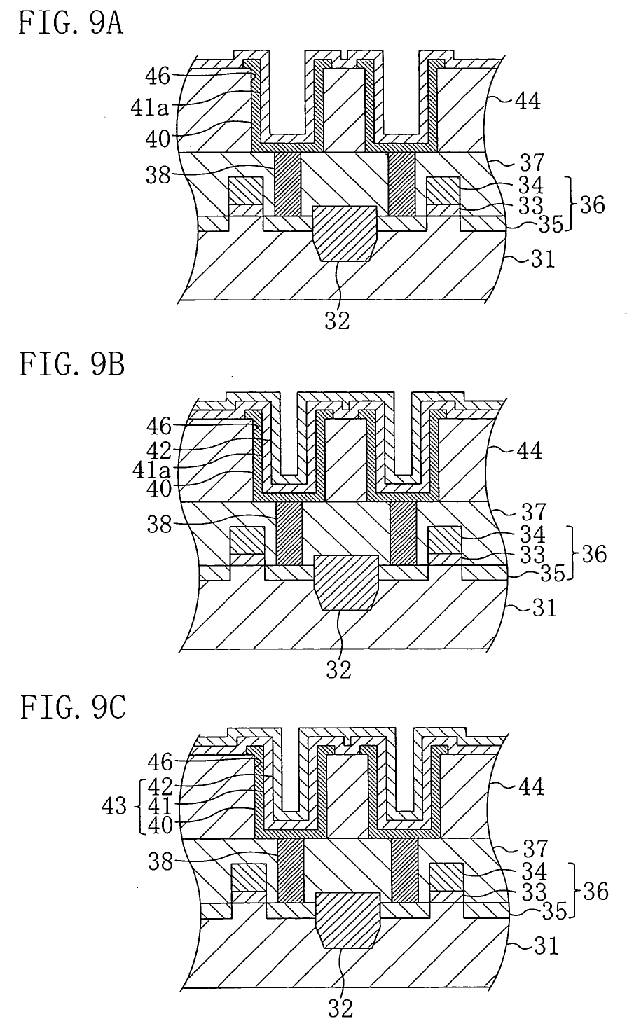

FIG. 8A to FIG. 8C and FIG. 9A to FIG. 9C are cross-sectional views illustrating a method for fabricating a capacitive insulating film of embodiment 2, a capacitive element and semiconductor storage device including the capacitive insulating film in the order of production steps. First, a plurality of memory cell transistors 36 are formed on a semiconductor substrate 31 made of silicon such that each memory cell transistor 36 includes an impurity-diffused region 35, a gate insulating film 33, and a gate insulating film 34, and such that the memory cell transistors 36 are separated by a device isolation region 32. Then, a first interlayer insulating film 37 is formed of SiO₂ or SiN so as to cover the memory cell transistors 36. Thereafter, a plurality of contact plugs 38 are formed of tungsten so as to penetrate through the first interlayer insulating film 37 and to be electrically connected to the impurity-diffused region 35 of the respective memory cell transistors 36, resulting in the structure shown in FIG. 8A.

Then, a second interlayer insulating film 44 is formed over the first interlayer insulating film 37. Thereafter, the second interlayer insulating film 44 is etched to form a plurality of openings 46 through which the contact plugs 38 are exposed as shown in FIG. 8B.

Then, a lower electrode 40 is formed so as to cover the bottom and side wall of the openings 46 as shown in FIG. 8C. Herein, the upper layer of the lower electrode 40 is formed by depositing a conductive metal oxide by MOCVD. It should be noted that the lower electrode 40 is formed such that the lower surface of the lower electrode 40 is in contact with the contact plug 38.

Then, a precursor film 41a is formed of SBTN by MOCVD on the second interlayer insulating film 44 so as to cover the lower electrode 40 as shown in FIG. 9A. The thickness of the precursor film 41a is set in the range of 12.5 nm to 90 nm by adjusting the deposition time of MOCVD.

Then, an upper electrode 42 is formed by MOCVD on the precursor film 41a as shown in FIG. 9B. Thereafter, a thermal treatment is carried out such that the precursor film 41a is crystallized to form a capacitive insulating film 41, whereby a semiconductor storage device shown in FIG. 9C is completed.

In the thermal treatment for crystallizing the precursor film 41a, a thermal treatment is first performed at 500° C. to 700° C. to determine the nuclei density, and then, crystal growth is promoted at 800° C., such that the capacitive insulating film 41 has a grain size of 10 nm to 200 nm. With generally uniform grain size, generation of voids between grains due to a grain size difference can be suppressed. It should be noted that the grain size in this example means a longest diameter of a crystal observed in a cross section of the capacitive insulating film 41 cleaved at a certain position.

In embodiment 2, the precursor film 41a itself shrinks only 15%. Therefore, voids are scarcely generated in the crystallized capacitive insulating film 41.

This is because in embodiment 2 the precursor film 41a is formed by MOCVD and, accordingly, the amount of organic components contained in the precursor film 41a is far smaller than that contained in a film formed by coating. When the film formed by coating is used, in the process of crystallizing a precursor film into a capacitive insulating film, volatilization of solvent and crystallization into a ferroelectric occur. When the film is formed by MOCVD, only crystallization of the precursor into a ferroelectric occurs while volatilization of solvent does not occur. Thus, when the precursor film is formed by MOCVD, the weight of the film scarcely varies, and the shrinkage ratio is in the range of about 0% to 15%. If the precursor film is formed by coating, the film would shrink about 15% to 20% due to volatilization of solvent. Therefore, voids would be likely to occur in a capacitive insulating film obtained after crystallization.

In embodiment 2, the upper layer of the lower electrode 40, which is in contact with the crystallized capacitive insulating film 41, and the upper electrode 42 are made of a conductive metal oxide, such as IrO₂, RuO₂, SrRuO₃, or the like. Thus, in the crystallization of the precursor film 41a, the upper layer of the lower electrode 40 and the upper electrode 42 shrink only about 0% to 10%.

Thus, in embodiment 2, the shrinkage ratios of the electrodes are smaller than that of the precursor film, and therefore, the electrodes are compressed by the capacitive insulating film. Hence, generation of voids in the upper layer of the lower electrode 40 and the upper electrode 42 is prevented.

As a result, generation of voids in the upper layer of the lower electrode 40 and the upper electrode 42 is more suppressed as compared with a structure wherein the upper layer of the lower electrode 40 and the upper electrode 42 are formed of Pt.

By forming a capacitive element using the fabrication method of embodiment 2, the void occupancy rate in a capacitive insulating film, an upper electrode and a lower electrode of the capacitive element is 20% or lower. Therefore, a capacitive element which includes a capacitive insulating film with small current leakage and high breakdown voltage and is resistant to stress migration, and a highly-reliable, densely-integrated semiconductor storage device can be realized.

In embodiment 2, the capacitive insulating film is formed of SBTN but may be formed of (Bi_{w}NdₓLa_{1-w-x})₄(Hf_{y}Zr_{z}Ti_{3-y-z})O₁₂ (0≦w≦1, 0≦x≦1, 0≦w+x≦1, 0≦y≦1, 0≦1, 0≦y+z≦1). In this case, it is possible that a thermal treatment is first performed at 400° C. to 600° C., through which the nuclei density is determined, and thereafter, crystal growth is promoted at 700° C., such that the grain size is 10 nm to 200 nm.

In the case where the capacitive insulating film is formed of Pb(HfₓZr_{y}Ti_{1-x-y}) O₃ (0≦x≦1, 0≦y≦1, 0≦x+y≦1), it is possible that a thermal treatment is first performed at 400° C. to 500° C., through which the nuclei density is determined, and thereafter, crystal growth is promoted at 650° C., such that the grain size is 10 nm to 200 nm.

The opening 46 in which the capacitive element is formed may have a diameter and a depth in the range of 0.2 μm to 1.0 μm, respectively. In order to enlarge the surface area of the lower electrode and increase the amount of storable charges, the ratio of depth to diameter is preferably 1 or greater.

### EMBODIMENT 3

Hereinafter, embodiment 3 of the present invention is described with reference to the drawings.

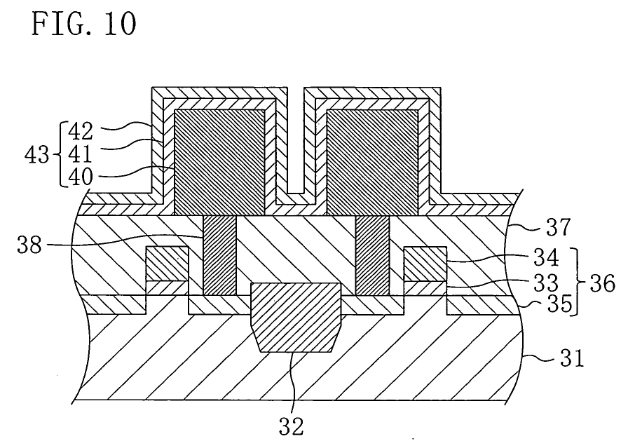

FIG. 10 is a cross-sectional view showing a principal part of capacitive insulating film of embodiment 3 and a capacitive element and semiconductor storage device including the capacitive insulating film in a cross section taken along a word line. The capacitive element of embodiment 2 has a three-dimensional geometry such that the capacitive insulating film covers not only the upper surface but also the side surface of the lower electrode. More specifically, the capacitive element of embodiment 2 has a so-called “convex” electrode as shown in FIG. 10. It should be noted that, in FIG. 10, components equivalent to those of FIG. 7 are denoted by the same reference numerals used in FIG. 7, and the descriptions thereof are herein omitted.

As shown in FIG. 10, a lower electrode 40 is provided on a first interlayer insulating film 37. The lower electrode 40 has a cylindrical shape. The diameter and height of the lower electrode 40 are in the range of 0.2 μm to 1.0 μm, and the ratio of height to diameter is 1 or greater. The lower electrode 40 is a single-layer film or a multilayered film, which includes at least one of Ir, IrO₂, Ru, RuO₂, TiAlN, TaAlN, TiSiN and TaAlN. In the case where the lower electrode 40 is a multilayered film, the lower electrode 40 includes a lower layer which functions as an oxygen barrier and an upper layer formed of a conductive metal oxide, such as IrO₂, RuO₂, SrRuO₃, or the like, which is in contact with the capacitive insulating film. The thickness of the upper layer which is in contact with the capacitive insulating film is preferably 10 nm to 200 nm.

Provided over the lower electrode 40 is a capacitive insulating film 41 made of SBTN, which has a thickness of 12.5 nm to 90 nm. Provided over the capacitive insulating film 41 is an upper electrode 42 made of a conductive oxide, such as IrO₂, RuO₂, SrRuO₃, or the like, which has a thickness of 10 nm to 200 nm.

Also in embodiment 3, to form the capacitive insulating film 41, a precursor film 41a of SBTN is first formed, and then, a thermal treatment is performed at 500° C. to 700° C. to determine the nuclei density. Thereafter, crystal growth is promoted at 800° C., such that the capacitive insulating film 41 has a grain size of 10 nm to 200 nm. As a result, the void occupancy rate in the capacitive insulating film, the upper electrode and the lower electrode is 20% or lower. Therefore, a capacitive element which includes a capacitive insulating film with small current leakage and high breakdown voltage and is resistant to stress migration and a highly-reliable, densely-integrated semiconductor storage device can be realized.

### EMBODIMENT 4

Hereinafter, embodiment 4 of the present invention is described with reference to the drawings.

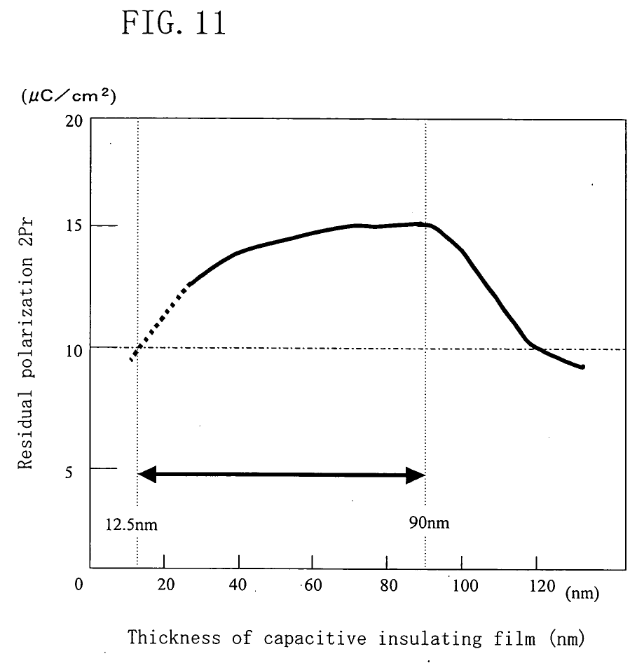

FIG. 11 illustrates a variation in residual polarization (2Pr) over the thickness of the capacitive insulating film 21 of the capacitive element having the flat-shape structure shown in FIG. 1. It should be noted that a dotted-line portion of the graph was estimated by extrapolation.

In capacitive element samples which were used for measurement, the lower electrode 20 was a layered film sequentially including from the bottom a TiAlN layer of a 100 nm thick, an Ir layer of 50 nm thick, and an IrO₂ layer of 100 nm thick. The upper electrode 22 was an IrO₂ film of 50 nm thick. The capacitive insulating film 21 was an SBTN film. In the process of forming the capacitive insulating film 21, a precursor film was first formed by MOCVD and subjected to a thermal treatment at 700° C. to determine the nuclei density. Thereafter, crystal growth was promoted at 800° C. to achieve a grain size of 10 nm to 200 nm. The measurement voltage was 1.0 V, which was expected to be the minimum voltage in the use of the capacitive element.

As seen from FIG. 11, the value of residual polarization increases as the thickness of the capacitive insulating film 21 increases in the range of 12.5 nm to 90 nm. This is because, as described above, voids scarcely exist due to film shrinkage in a capacitive insulating film of the present invention, and therefore, the polarization that is saturated by voltage application increases as the film thickness increases. However, when the thickness of the capacitive insulating film 21 is greater than 90 nm, the residual polarization decreases as the film thickness increases. This is because, when the capacitive insulating film 21 of a ferroelectric is thick, a change of volume which is caused by a change in structure during crystallization is nonnegligible, and voids are generated due to a grain size difference caused during the growth of grains.

Thus, in view of the design rule, the thickness of the capacitive insulating film of the present invention is preferably 100 nm or less. In view of the residual polarization characteristic, the thickness of the capacitive insulating film is preferably 90 nm or less. If the residual polarization is 10 μC/cm² or smaller, the possibility of a malfunction of the semiconductor storage device increases. Therefore, the thickness of the capacitive insulating film is preferably 12.5 nm or more.

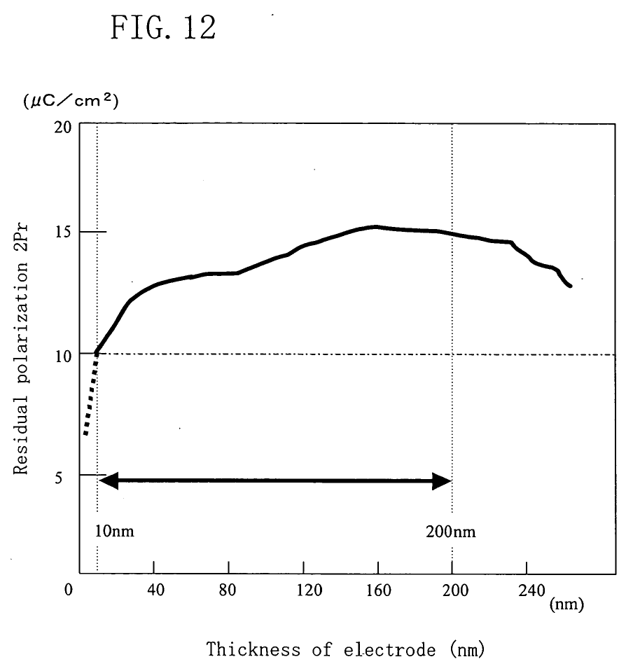

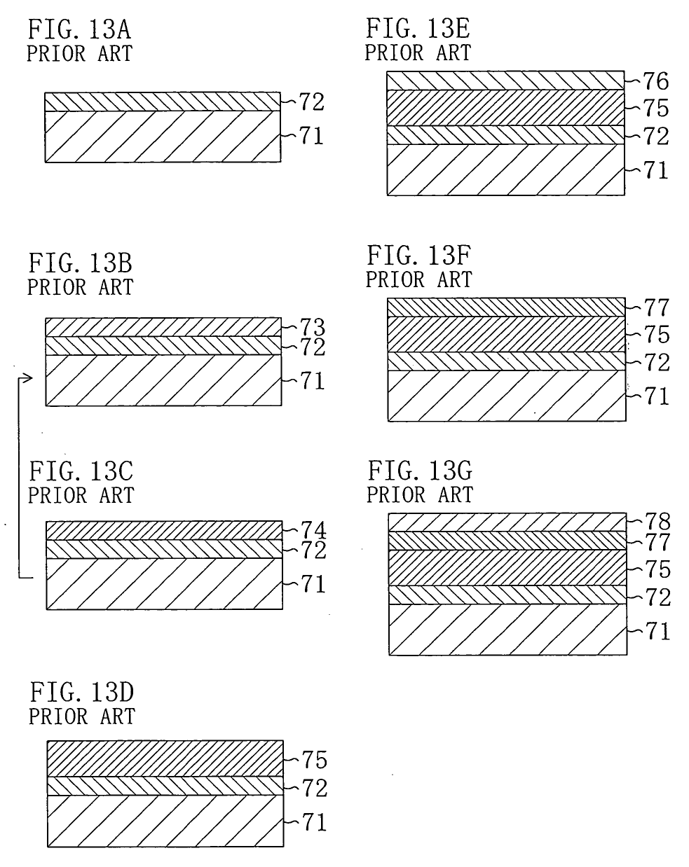

FIG. 12 shows a variation in residual polarization over the thickness of the upper electrode 22 formed of a conductive metal oxide with the thickness of the capacitive insulating film 21 being 50 nm. It should be noted that a dotted-line portion of the graph was estimated by extrapolation. As seen from FIG. 12, the thickness of the upper electrode 22 formed of IrO₂ is in the range of 10 nm or less, the polarization characteristic sharply decreases. This is because, when the upper electrode 22 is thin, the influence of the grain boundary of the upper electrode 22 is nonnegligible, and the electric field applied to the capacitive insulating film 21 decreases so that the displacement of ions in ferroelectric crystals decreases.

As previously described, if the residual polarization is 10 μC/cm² or smaller, the possibility of a malfunction of the semiconductor storage device increases. Therefore, the thickness of the upper electrode 22 is preferably 10 nm or more. In order not to hinder a thermal treatment of the capacitive insulating film, the thickness of the upper electrode 22 is preferably 200 nm or less.

In embodiment 4, although only the thickness of the upper electrode is considered in the above example, the thickness of the lower electrode is preferably in the range of 10 nm to 200 nm because the lower electrode has the same characteristics as those described above for the upper electrode.

Although in the above example the electrode material is IrO₂, the same effects are achieved even when another conductive oxide, e.g., RuO₂ or SrRuO₃, is used or even when platinum, or the like, is used. In the case where the upper or lower electrode is a multilayered film, the thickness of a constituent layer which is in contact with the capacitive insulating element may be in the range of 10 nm to 200 nm.

In a capacitive element of embodiment 4, to secure a sufficiently large ratio of electric charges which determine data “0” and data “1” stored in the capacitive element such that the data storage characteristic is improved, the voltage applied to a capacitive insulating film is preferably in the range of 0.3 V to 1.8 V. Further, the same effects can be achieved when the strength of the electric field applied to the capacitive insulating film is 200 kV/cm or greater. For example, in the capacitive element of embodiment 4, when switching is carried out with a pulse wave of 1.8 V, the residual polarization amount of at least 10 μC/cm² can be attained.

In the examples of embodiments 1-4, an insulating film of the present invention is used as a capacitive insulating film of a capacitive element. However, the insulating film of the present invention may be used as a gate insulating film which is provided under a gate electrode of a ferroelectric field effect transistor (ferroelectric FET), or the like.

### INDUSTRIAL APPLICABILITY

An insulating film of the present invention, a capacitive element and semiconductor storage device including the insulating film, and fabrication methods thereof realize an insulating film of a ferroelectric which has no voids so that the ferroelectric characteristic does not deteriorate, a capacitive element and semiconductor storage device with small current leakage and high breakdown voltage, and fabrication methods thereof, are therefore useful for an insulating film of a ferroelectric, a capacitive element and semiconductor storage device including the insulating film, and fabrication methods thereof.

What is claimed is:

1. An insulating film comprising a ferroelectric film formed above a substrate, wherein in any cross section of the ferroelectric film which is perpendicular to the substrate, a sum of the widths of voids generated in the ferroelectric film which are measured in a direction perpendicular to the thickness direction of the ferroelectric film is 20% or less of a unit width.

2. The insulating film of claim 1, wherein the ferroelectric film has a thickness of 100 nm or less.

3. The insulating film of claim 1, wherein the ferroelectric film is formed of any one of (Sr_{w}CaₓBa_{1-w-x})Bi₂(Ta_{y}Nb_{z}V_{1-y-z})₂O₉ (w, x, y, and z are in the range of 0 to 1, w+x and y+z are 1 or less), Pb(HfₓZr_{y}Ti_{1-x-y})O₃ (x and y are in the range of 0 to 1, x+y is 1 or less), and (Bi_{w}NdₓLa_{1-w-x})₄(Hf_{y}Zr_{z}Ti_{3-y-z})O₂ (w, x, y, and z are in the range of 0 to 1, w+x and y+z are 1 or less).

4. The insulating film of claim 1, wherein the ferroelectric film is a capacitive insulating film of a capacitive element of a semiconductor storage device.

5. The insulating film of claim 1, wherein the ferroelectric film is a gate insulating film of a ferroelectric field effect transistor.

6. A capacitive element, comprising:
a lower electrode formed above a semiconductor substrate;
a capacitive insulating film formed of a ferroelectric on the lower electrode so as to have a thickness of 100 nm or less, wherein in any cross section of the capacitive insulating film which is perpendicular to the semiconductor substrate, a sum of the widths of first voids generated in the capacitive insulating film which are measured in a direction perpendicular to the thickness direction of the capacitive insulating film is 20% or less of a unit width; and
an upper electrode formed on the capacitive insulating element.

7. The capacitive element of claim 6, wherein in any of the upper electrode and the lower electrode, a sum of the widths of second voids generated in the electrode which are measured in a direction perpendicular to the thickness direction of the electrode is 20% or less of a unit width.

8. The capacitive element of claim 6, wherein the thickness of the capacitive insulating film is in the range of 12.5 nm to 90 nm.

9. The capacitive element of claim 6, wherein:
at least one of the lower electrode and the upper electrode contains a conductive metal oxide; and
the conductive metal oxide is in contact with the capacitive insulating film.

10. The capacitive element of claim 6, wherein at least one of the lower electrode and the upper electrode is a multilayered film.

11. The capacitive element of claim 6, wherein:
each of the lower electrode and the upper electrode is a single-layer film or a multilayered film; and
each of a film included in the lower electrode which is in contact with the capacitive insulating film and a film included in the upper electrode which is in contact with the capacitive insulating film has a thickness in the range of 10 nm to 200 nm.

12. The capacitive element of claim 6, wherein the voltage applied to the capacitive insulating film is in the range of 0.3 V to 1.8 V.

13. The capacitive element of claim 6, wherein the strength of an electric field applied to the capacitive insulating film is 200 kV/cm or greater.

14. The capacitive element of claim 6, wherein:
the capacitive insulating film is in contact with the upper or lower surface of the lower electrode; and
the ratio of height to width of the lower electrode is 1 or greater.

15. The capacitive element of claim 6, wherein:
the capacitive element is formed in an opening provided in an interlayer insulating film formed on the semiconductor substrate; and
the ratio of depth to diameter of the opening is 1 or greater.

16. The capacitive element of claim 6, wherein the ferroelectric is any one of (Sr_{w}CaₓBa_{1-w-x}) Bi₂(Ta_{y}Nb_{z}V_{1-y-z})₂O₉ (w, x, y, and z are in the range of 0 to 1, w+x and y+z are 1 or less), Pb(HfₓZr_{y}Ti_{1-x-y})O₃ (x and y are in the range of 0 to 1, x+y is 1 or less), and (Bi_{w}NdₓLa_{1-w-x})₄(Hf_{y}Zr_{z}Ti_{3-y-z})O₁₂ (w, x, y, and z are in the range of 0 to 1, w+x and y+z are 1 or less).

17. A semiconductor storage device, comprising:
a semiconductor substrate;
a lower electrode formed above the semiconductor substrate;
a capacitive insulating film formed of a ferroelectric on the lower electrode so as to have a thickness of 100 nm or less, wherein in any cross section of the capacitive insulating film which is perpendicular to the semiconductor substrate, a sum of the widths of voids generated in the capacitive insulating film which are measured in a direction perpendicular to the thickness direction of the ferroelectric film is 20% or less of a unit width;
an upper electrode formed on the capacitive insulating element;
a transistor formed on the semiconductor substrate, the transistor including a source region and a drain region;
an interlayer insulating film which covers the transistor; and
a plug electrode formed in the interlayer insulating film, one end of the plug electrode being electrically connected to the source region or the drain region, the other end of the plug electrode being electrically connected to the lower electrode.

18. A method for fabricating a capacitive element, comprising the steps of:
(a) forming a lower electrode above a semiconductor substrate;
(b) forming a precursor film of a capacitive insulating film of a ferroelectric on the lower electrode by a metal organic chemical vapor deposition method;
(c) forming an upper electrode on the precursor film; and
(d) crystallizing the precursor film by a thermal treatment to form a capacitive insulating film.

19. The fabrication method of claim 18, wherein step (d) is performed after step (c).

20. The fabrication method of claim 18, wherein the ferroelectric is any one of (Sr_{w}CaₓBa_{1-w-x})Bi₂(Ta_{y}Nb_{z}V_{1-y-z})₂O₉ (w, x, y, and z are in the range of 0 to 1, w+x and y+z are 1 or less), Pb(HfₓZr_{y}Ti_{1-x-y})O₃ (x and y are in the range of 0 to 1, x+y is 1 or less), and (Bi_{w}NdₓLa_{1-w-x})₄(Hf_{y}Zr_{z}Ti_{3-y-z})O₂ (w, x, y, and z are in the range of 0 to 1, w+x and y+z are 1 or less).

21. The fabrication method of claim 18, wherein:
step (d) includes a first thermal treatment through which the nuclei density is determined and a second thermal treatment for crystal growth; and
the grain size of the capacitive insulating film is in the range of 10 nm to 200 nm.

22. The fabrication method of claim 18, wherein the thickness of the capacitive insulating film is in the range of 12.5 nm to 90 nm.

23. The fabrication method of claim 18, wherein:
at least one of the lower electrode and the upper electrode contains a conductive metal oxide; and
the conductive metal oxide is in contact with the capacitive insulating film.

24. The fabrication method of claim 18, wherein at least one of the lower electrode and the upper electrode is a multilayered film.

25. The fabrication method of claim 18, wherein:
each of the lower electrode and the upper electrode is a single-layer film or a multilayered film; and
each of a film included in the lower electrode which is in contact with the capacitive insulating film and a film included in the upper electrode which is in contact with the capacitive insulating film has a thickness in the range of 10 nm to 200 nm.

26. The fabrication method of claim 18, wherein the capacitive element has a three-dimensional geometry such that the capacitive insulating film covers not only an upper surface but also a side surface of the lower electrode.

27. The fabrication method of claim 26, wherein the ratio of height to width of the lower electrode is 1 or greater.

28. The fabrication method of claim 18, further comprising, prior to step (a):
forming an insulating film on the semiconductor substrate; and
etching the insulating film to form an opening,
wherein step (a) includes forming the lower electrode on a bottom and side wall of the opening, and
the ratio of depth to diameter of the opening is 1 or greater.

29. The fabrication method of claim 18, wherein the upper electrode or the lower electrode is formed by a metal organic chemical vapor deposition method.

30. The fabrication method of claim 18, wherein at step (d), shrinkage of the precursor film is 15% or less.

31. The fabrication method of claim 30, wherein at step (d), shrinkage of the upper electrode and the lower electrode is 10% or less.

32. A method for producing a semiconductor storage device, comprising the steps of:
forming a transistor on a semiconductor substrate, the transistor including a source region and a drain region;
forming an interlayer insulating film so as to cover the transistor;
forming a plug contact so as to penetrate through the interlayer insulating film, the plug contact being electrically connected to the source region or the drain region;
forming a lower electrode on the interlayer insulating film so as to be electrically connected to the plug contact;
forming a precursor film of a capacitive insulating film of a ferroelectric on the lower electrode by a metal organic chemical vapor deposition method;
forming an upper electrode on the precursor film; and
crystallizing the precursor film by a thermal treatment to form a capacitive insulating film.

33. A method for fabricating an insulating film, comprising the steps of:
forming a precursor film of a ferroelectric film above a semiconductor substrate by a metal organic chemical vapor deposition method; and
crystallizing the precursor film by a thermal treatment to form a ferroelectric film,
wherein in the thermal treatment, shrinkage of the precursor film is 15% or less.

34. The fabrication method of claim 33, wherein the ferroelectric film has a thickness of 100 nm or less.

35. The fabrication method of claim 33, wherein the ferroelectric is any one of (Sr_{w}CaₓBa_{1-w-x})Bi₂(Ta_{y}Nb_{z}V_{1-y-z})₂O₉ (w, x, y, and z are in the range of 0 to 1, w+x and y+z are 1 or less), Pb(HfₓZr_{y}Ti_{1-x-y})O₃ (x and y are in the range of 0 to 1, x+y is 1 or less), and (Bi_{w}NdₓLa_{1-w-x})₄(Hf_{y}Zr_{z}Ti_{3-y-z})O₁₂ (w, x, y, and z are in the range of 0 to 1, w+x and y+z are 1 or less).
